(19) United States
(12) Patent Application Publication
(10) Pub. No.: US 2006/0207508 A1
(43) Pub. Date: Sep. 21, 2006

(54) Film deposition using a spring loaded contact finger type shadow frame

(75) Inventor: Samuel Leung, San Jose, CA (US)

Correspondence Address: PATTERSON & SHERIDAN, LLP, 3040 POST OAK BOULEVARD, SUITE 1500, HOUSTON, TX, 77056, US

(73) Assignee: Applied Materials, Inc.

(21) Appl. No.: 11/367,230

(22) Filed: Mar. 2, 2006

Related U.S. Application Data
(60) Provisional application No. 60/678,390, filed on May 5, 2005.
(60) Provisional application No. 60/662,530, filed on Mar. 16, 2005.

(51) Int. Cl. C23C 16/00

(52) U.S. Cl. 118/728

(57) ABSTRACT

The present invention relates generally to a clamping and alignment assembly for a substrate processing system. The clamping and aligning assembly generally includes a shadow frame, a floating shadow frame and a plurality of insulating alignment pins. The shadow frame comprises a plurality of fingers extending inwardly therefrom and is shaped to accommodate a substrate. The fingers comprise a spring loaded assembly for aligning and stabilizing a substrate on a support member during processing. The insulating alignment pins are disposed at a perimeter of a movable support member and cooperate with an alignment recess formed in the shadow frame to urge the shadow frame into a desired position. Preferably, the floating shadow frame is disposed on the insulating alignment pins in spaced relationship between the support member and the shadow frame to shield the perimeter of the support member during processing.

### CROSS-REFERENCE TO RELATED APPLICATIONS

This application claims benefit of U.S. provisional patent application Ser. No. 60/678,390 (APPM/010104L02), filed May 5, 2005, and United States provisional patent application serial number 60/662,530 (APPM/010104L), filed Mar. 16, 2005, which are herein incorporated by reference.

### BACKGROUND OF THE INVENTION

1. Field of the Invention

The present invention relates to a method and apparatus for use in processing a substrate. More particularly, the invention relates to a contact finger shadow frame for stabilizing a substrate during processing.

2. Description of the Related Art

In the fabrication of flat panel displays, transistors, and liquid crystal cells, metal interconnects and other features are formed by depositing and removing multiple layers of conducting, semiconducting and dielectric materials from a glass substrate. Glass substrate processing techniques include plasma-enhanced chemical vapor deposition (PECVD), physical vapor deposition (PVD), etching and the like. Plasma processing is particularly well-suited for the production of flat panel displays because of the relatively low processing temperatures required to deposit a good quality film.

In general, plasma processing involves positioning a substrate on a support member (often referred to as a susceptor or heater) disposed in a vacuum chamber and striking a plasma adjacent to the upper exposed surface of the substrate. The plasma is formed by introducing one or more process gases into the chamber and exciting the gases with an electrical field to cause dissociation of the gases into charged and neutral particles. A plasma may be produced inductively, e.g., using an inductive RF coil, and/or capacitively, e.g., using parallel plate electrodes, or by using microwave energy.

During processing, the edge and backside of the glass substrate as well as the internal chamber components must be protected from deposition. Typically, a decomposition-masking device or shadow frame, is placed about the periphery of the substrate to prevent processing gases or plasma from reaching the edge and backside of the substrate and to hold the substrate on a support member during processing. The shadow frame may be positioned in the processing chamber above the support member so that when the support member is moved into a raised processing position the shadow frame is picked up and contacts an edge portion of the substrate. As a result, the shadow frame covers several millimeters of the periphery of the upper surface of the substrate, thereby preventing edge and backside deposition on the substrate.

However, while conventional shadow frames may reduce edge and backside deposition on a substrate, the usable area of the substrate is greatly reduced. Typically, shadow frames comprise a lip portion extending over the edge of the substrate. The lip prevents any portion of the masked area of the substrate from receiving deposition, an effect known as edge exclusion. Consequently, each processed substrate includes an unprocessed, unusable portion which reduces the usable surface area on a substrate and results in lower productivity of the processing system.

One attempt to reduce the edge exclusion is the use of finger-type shadow frames. Finger-type shadow frames comprise a plurality of “fingers” or tabs extending outwardly from the shadow frame to stabilize a substrate during processing. The fingers are disposed around the edge of a substrate, thereby increasing the amount of usable substrate surface area as compared to the lip-type shadow frame which comprehensively covers the edge of the substrate. One exemplary shadow frame is found in U.S. Pat. No. 6,355,108, issued Mar. 12, 2002, entitled “Film Deposition Using A Finger Type Shadow Frame,” filed Jun. 11, 1999, herein incorporated by reference. However, if the shadow frame is not correctly aligned with the susceptor, the tips of one of the contact fingers may exert too much pressure upon the substrate risking substrate breakage.

Further, finger-type shadow frames complicate control of the plasma during processing. Successful processing requires a uniform plasma density across the entire upper surface of a substrate during processing. Anomalies in the plasma density result in non-uniform deposition of films on the substrate leading to defective devices and thus further reducing the throughput of the processing system. In the case of flat panel display manufacturing, maintaining a uniform plasma at the perimeter of the substrate is particularly difficult due to various components of the vacuum system which can act as energy sinks. In using finger-type shadow frames, for example, the shadow frame and the outermost edge of the substrate define a gap provided to prevent arcing which can occur between the shadow frame and the substrate resulting in damage to the substrate. However, the gap exposes the perimeter of the support member to the plasma and provides a ground to drain the plasma constituents. Thus, the plasma density at a perimeter of the substrate is often substantially less than the plasma density over the central portion of the substrate. Since deposition thickness is related to the plasma uniformity, non-uniform deposition results unless plasma density is adjusted at the perimeter.

Another problem with flat panel display processing is the detrimental effects of thermal dynamics. During processing, the support member is heated by means of a heating element, such as a resistive coil, or by other methods in order to heat the substrate disposed thereon. Uniform heat conduction between the support member and the substrate are necessary to ensure uniform deposition. Where the thermal profile across the substrate is not uniform, i.e., where the profile exhibits relative hot and cold spots, the deposition of material onto the substrate is non-uniform and results in defective devices. Flat panel displays are particularly susceptible to the detrimental effects of thermal non-uniformity because of the area of the substrates exposed to deposition material as compared to their thicknesses, and because of the differences in the thermal conductivity of the substrates, typically comprising glass, and the support member, typically comprising a metal. For exam pie, the substratet temperature may be about 30-60° C. less than the temperature of the support member which may be heated to a temperature between about 250-470° C. The support member also will expand at the localized hot spots resulting in warping or bowing.

Therefore, there is a need for a clamping assembly that minimizes edge exclusion while providing sufficient clamping force to stabilize a substrate during processing without damaging the substrate. Further, there is a need for a clamping assembly that inhibits the drainage of plasma to chamber components.

### SUMMARY OF THE INVENTION

The present invention generally provides an apparatus for supporting a substrate comprising a substrate support member and a horizontally alignable shadow frame comprising a plurality of fingers for stabilizing a substrate disposed on the substrate support member wherein the fingers comprise an actuator assembly. The actuator assembly comprises a spring loaded assembly and a hinge assembly. The spring loaded assembly comprises a mounting post with a spring disposed thereon wherein the mounting post is attached to a substrate contact member assembly.

In still another embodiment, a substrate processing chamber is provided having a clamping and aligning assembly disposed therein. The processing chamber defines a processing region and includes a support member selectively movable into the processing region. The clamping and aligning assembly includes a shadow frame, a floating shadow frame, and a plurality of insulating alignment pins. The shadow frame is disposed in the processing chamber adjacent to the processing region and is shaped to accommodate a substrate. A plurality of fingers are disposed on the shadow frame and extend inwardly therefrom wherein a terminal end of each finger comprises an actuator assembly further comprising a hinge assembly and a spring loaded assembly. The insulating alignment-pins are disposed at a perimeter of the support member and include an upper tapered surface that cooperates with a corresponding, shadow frame into a desired position during the upward motion of the insulating alignment pins. Preferably, the floating shadow frame is disposed on the insulating alignment pins in spaced relationship to the support member and below the shadow frame to shield the perimeter of the support member during processing.

In yet another embodiment, a method for processing a substrate is provided, comprising: supporting a substrate member; positioning a floating shadow frame on the substrate support member wherein the floating shadow frame extends inwardly under a substrate receiving position on the support member; and aligning a shadow frame comprising a plurality of fingers for stabilizing a substrate disposed on the substrate support member wherein the fingers comprise an actuator assembly with a contact surface member assembly for contacting substrates.

### BRIEF DESCRIPTION OF THE DRAWINGS

So that the manner in which the above recited features, advantages and objects of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 is a cross sectional view of a processing chamber.

FIG. 2 is a top view of a shadow frame stabilizing a substrate.

FIG. 3A is a partial cross sectional view of a clamping and aligning assembly including the shadow frame of FIG. 2.

FIG. 3B is an enlarged view of the terminal end of the finger of FIG. 3A.

FIG. 4 is a partial cross sectional view of a clamping and aligning assembly in a substrate receiving position.

FIG. 5 is a partial cross sectional view of a clamping and aligning assembly in a substrate transferring position.

FIG. 6 is a partial cross sectional view of a clamping and aligning assembly in a substrate processing position.

FIG. 7 is a schematic view of a contact finger assembly in a substrate receiving position.

FIG. 8 is a schematic view of a contact finger assembly in a substrate transferring position.

FIG. 9 is a schematic view of a contact finger assembly in a substrate processing position.

### DETAILED DESCRIPTION

Embodiments of the present invention are directed to processing flat substrates comprising materials such as glass, polymers or other suitable substrate materials. These embodiments may be used in processing chambers including but not limited to CVD, PVD, PECVD, or any other suitable deposition process. The present invention may also be used in the processing of OLED (Organic Light-Emitting Diode) flat panel substrates (typically polymer substrates), of solar panels (typically glass substrates), and semiconductor substrates.

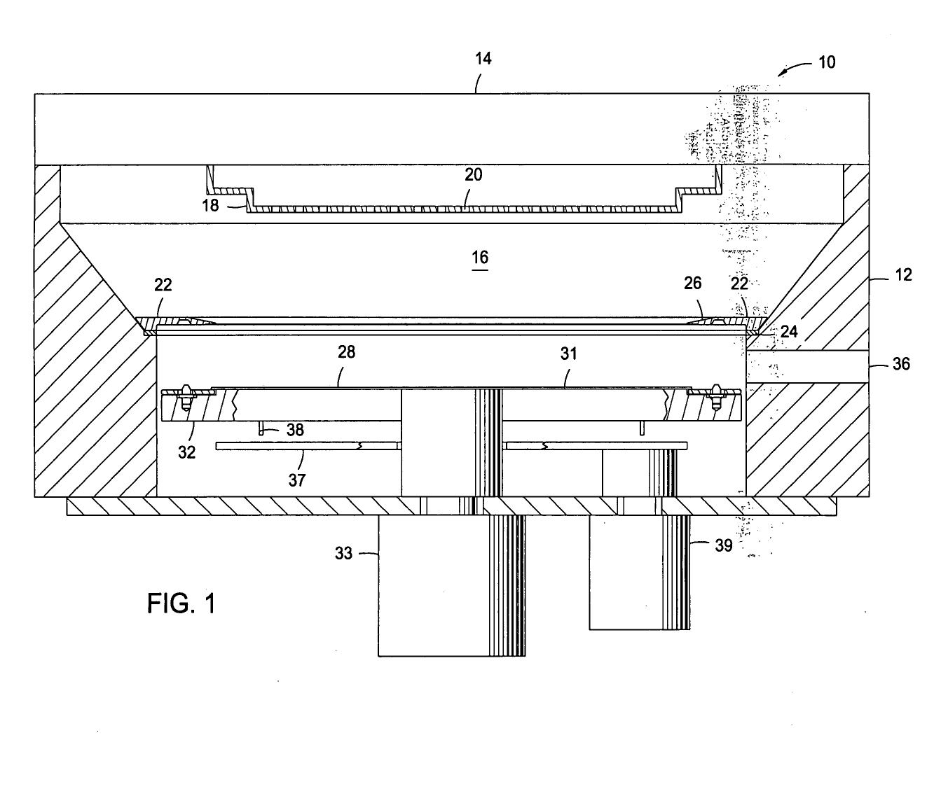

FIG. 1 is a cross section of an exemplary processing chamber 10 of the present invention adapted for processing flat panel displays. The processing chamber. 10 comprises a body 12 and a lid 14 disposed on the body 12. The processing chamber 10 defines a cavity which includes a processing region 16. A gas dispersion plate 18 is mounted to the lid 14 and defines the upper boundary of the processing region 16. A plurality of holes 20 are formed in the gas dispersion plate 18 to allow delivery of processing gases therethrough. A shadow frame 22 is shown disposed on a ledge 24 of the body 12. The shadow frame 22 includes a plurality of fingers 26 extending inwardly into the processing region 16 and positioned to contact a substrate in a processing position.

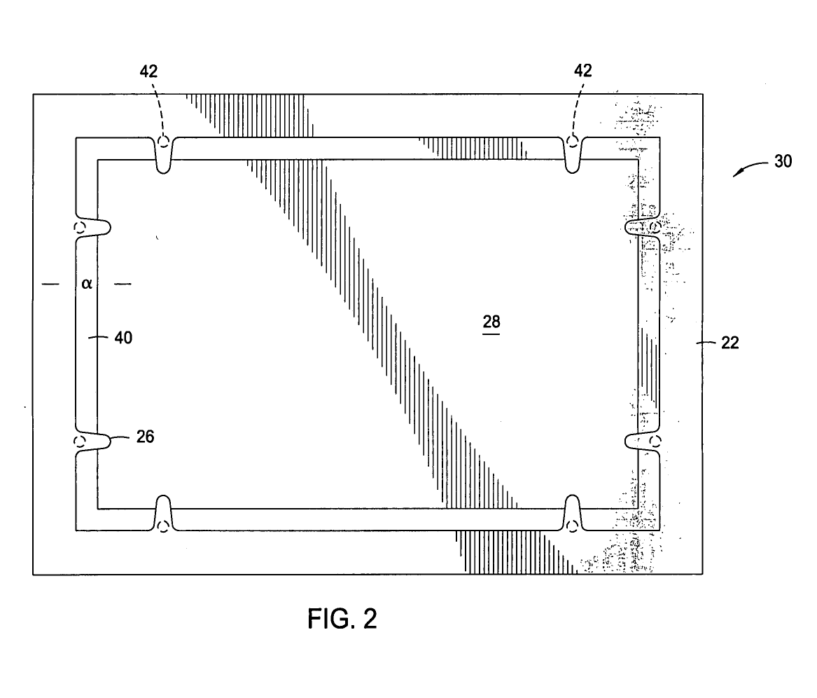

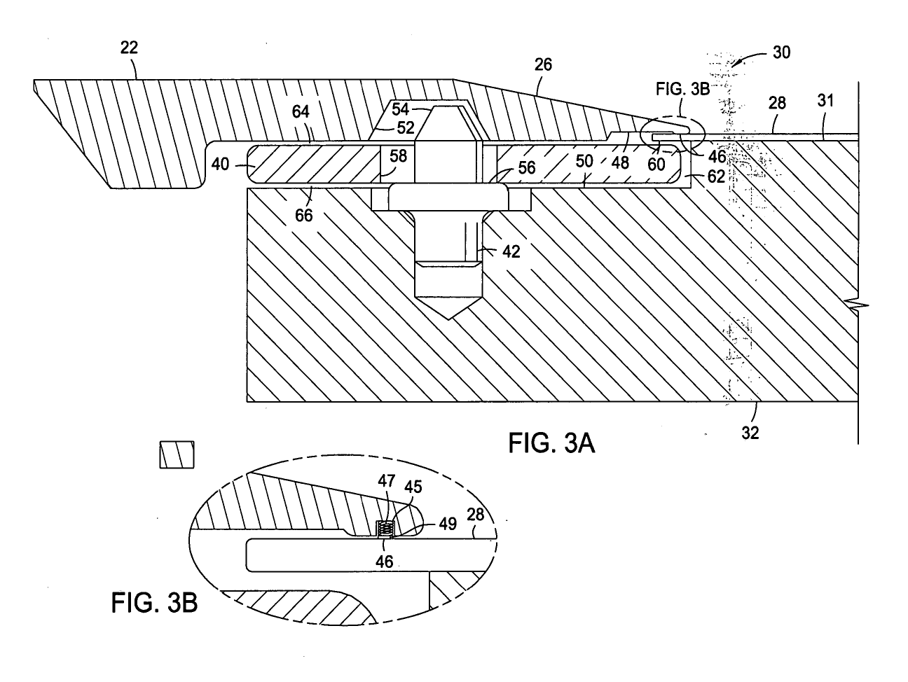

FIG. 2 is a top view of the shadow frame 22 shown disposed on a substrate 28. The shadow frame 22 is substantially rectangular and defines the usable area of the substrate 28. The shadow frame 22 is part of a clamping and aligning assembly 30 described in detail with reference to FIGS. 3A-6.

Referring again to FIG. 1, a movable support member 32, also referred to as a susceptor or heater, is disposed in the processing chamber 10 and is actuated by a motor 33. In a raised processing position, the support member 32, having the substrate 28 disposed on an upper surface 31 thereof, lifts the shadow frame 22 from the ledge 24 and defines the lower boundary of the processing region 16 such that the substrate 28 is positioned in the processing region 16. In a lowered position, the support member 32 can receive a substrate from a robot blade. The substrate is introduced into the chamber 10 through an opening 36 formed in the body 12 which is selectively sealed by a slit valve mechanism (not shown). Lift pins 38 (preferably four) are slidably disposed through the support member 32 and are adapted to hold a substrate at an upper end thereof. The lift pins 38 are actuatable by an elevator plate 37 and a motor 39 coupled thereto. The operation of the processing chamber 10 will be discussed in greater detail below.

FIG. 3A is a partial cross section of the clamping and aligning assembly 30 shown in a processing position. In general, the clamping and aligning assembly 30 comprises the shadow frame 22, a floating shadow frame 40, and a plurality of alignment pins 42 supported on the support member 32. However, the presence of the floating shadow frame 40 is dependent upon the RF power. At lower RF power, arcing is not a major problem and as a result, the floating shadow frame 40 may not be required. Although preferably separate components, the shadow frame 22, floating shadow frame 40, and a plurality of alignment pins 42 cooperate during processing in the manner described below.

The shadow frame 22 is preferably a unitary body shaped to accommodate a substrate (rectangular in the case of flat panel glass substrates as shown in FIG. 2) and is preferably constructed of a metal, such as aluminum, anodized aluminum, or other alloys; but may also comprise other suitable materials such as ceramic. The shadow frame 22 comprises a plurality of fingers 26 extending over an overhanging edge portion 60 of the substrate 28. Referring to FIG. 3B, in one embodiment, a terminal end of each finger 26 provides a spring 47 attached to a contact member 49. The spring 47 is attached in a recessed portion 45 of the terminal end of the fingers 26 (shown in FIG. 3B). The contact member 49 can be annular or any other suitable shape. The contact member 49 is generally ceramic but can also be made of other suitable materials that do not react with process chemistries. The contact member 49 has a contact surface 46 that defines the portion of the shadow frame 22 that maintains contact with the substrate 28 during processing. Preferably, the contact surface 46 is minimized so that the potential for damage to the substrate 28 caused by the contact of the shadow frame 22 and the substrate 28 is minimized. The contact surface 46 may include rounded surfaces such as shown in FIG. 3A and FIG. 3B or any other smooth surface. The rounded surfaces are adapted to reduce possible damage to the substrate 28 due to mechanical and thermal stresses during processing. The contact member 49 helps distribute the force applied to the substrate 28 to help prevent breakage. Known shadow frames typically comprise clamping mechanisms having sharp corners. Such sharp corners can scratch or fracture substrates when brought into contact therewith such as during the loading and unloading of the substrate from the process chamber. Further, during processing, the substrate and the shadow ring experience expansion and contraction causing-mechanical stress therebetween often resulting in damage to the substrate.

A roof portion 48 of the fingers 26 forms a recess outwardly of the contact surface 46. The roof portion 48 is in spaced relation from the substrate 28 so that contact at the outermost edge of the substrate 28 is avoided. Contact with the substrate 28 is preferably maintained only at the contact surface 46. Thus, the contact surface 46 and the roof portion 48 cooperate to minimize contact with the substrate 28. Further, the roof portion 48 is spaced from the substrate 28 to accommodate any thermal expansion of the shadow frame 22 and/or the substrate 28.

The spring 47 is generally a compression spring, coil spring, or flat spring. The spring 47 can be conical, barrel shaped, hourglass shaped, or straight. The spring 47 is attached in a recessed portion 45 of the finger 26 (shown in FIG. 3B) but may also be attached in other locations. The spring 47 comprises suitable compressive materials such as aluminum, stainless steel (e.g. INCONEL®) and other high strength, corrosion resistant metal alloys that do not react with process chemistries.

In another embodiment, the contact finger comprises a flexible material that can flex in order to further distribute the force provided to the substrate.

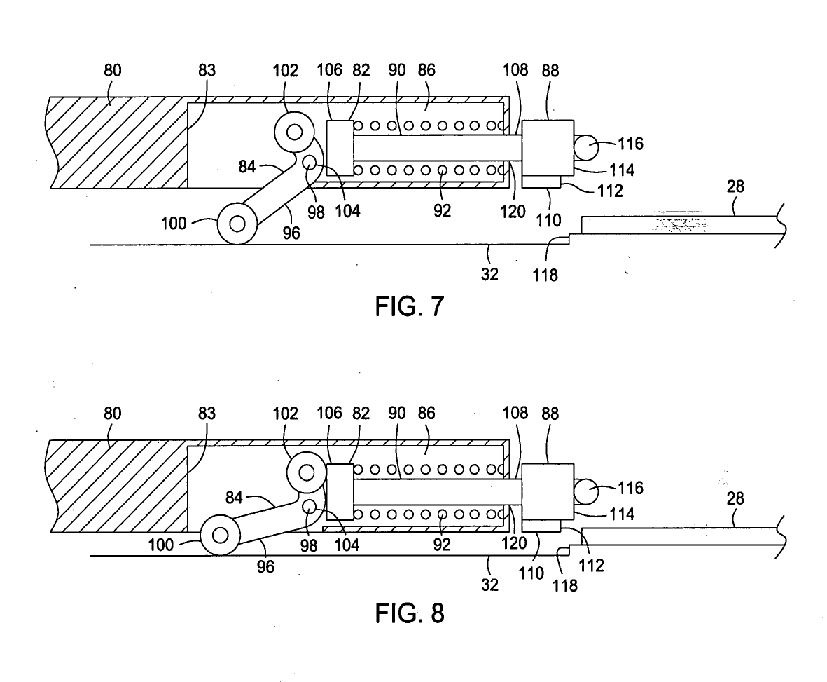

In yet another embodiment, described in FIGS. 7-9, the contact finger 80 comprises an actuator assembly 82, located in a channel 83 of the terminal end of the contact finger 80, capable of aligning and stabilizing the substrate 28 on the susceptor 32. FIG. 7 shows the contact finger 80 in a substrate 28 receiving position with the actuator assembly 82 in a disengaged position. The actuator assembly 82 comprises a hinge assembly 84 and a spring loaded assembly 86.

The hinge assembly 84 is attached in the channel 83 of the contact finger 80 along an axis. The hinge assembly 84 comprises a hinge 96, a pin 98, first contact surface 100 and a second contact surface 102. The hinge 96 rotates about a pivot point 104 about an axis. The hinge 96 can be rigid maintaining a 90° angle or can be flexible when the pivot point 104 includes a flexible pivoting member such as a wrap clutch spring. The hinge 96 may be attached in the channel 83 of the contact finger 80 by a pin 98 or other well known attachment methods. The hinge assembly 84 includes two contact surfaces 100, 102. A first contact surface 100 receives physical communication from the susceptor 32 when the susceptor 32 is raised to contact the shadow frame. After contact between the first contact surface 100 and the susceptor 32, the hinge 96 rotates about the pivot point 104 thus causing the second contact surface 102 to physically communicate with the proximal end 106 of the spring loaded assembly 86 of the contact finger 80 at an area.

The first contact surface 100 and the second contact surface 102 can comprise any actuating mechanism made of a material that does not react with process chemistries such as ceramic rollers which can be attached to the hinge 96 using common attachment methods.

The spring loaded assembly 86 comprises a movable mounting post 90 with a spring 92 disposed on the movable mounting post 90, attached to a substrate contacting member 88. The movable mounting post 90 is a generally cylindrical post which is sized and shaped to be slidably disposed within the channel 83 of the contact finger 80. The movable mounting post 90 comprises a proximal end 106, adjacent to the second contact surface 102, and a reduced distal end 108. It should be noted that the movable mounting post 90 has a tapered lateral cross-sectional area so as to define an enlarged portion, the proximal end 106 and the reduced distal end 108, the diameter of the enlarged portion being greater than the diameter of the reduced portion. The distal end 108 fits through a hole 120 in the terminal end of the contact finger 80 where it is attached to the substrate contacting member assembly 88.

The spring 92 is sized and shaped to be disposed within the channel 83 of the contact finger 80, and comprises a first end and a second end. The spring 92 comprises any suitable compressive material such as aluminum, stainless steel (e.g. INCONEL®) and other high strength, corrosion resistant metal alloys that do not react with process chemistries.

The spring-loaded assembly 86 is positioned within the contact finger 80 in the following manner. The movable mounting post 90 is disposed in the channel 83 such that the proximal end 106 of the movable mounting post 90 is adjacent the hinge assembly 84. The spring 92 is placed on the distal end 108 of the movable mounting post 90 such that the first end of the spring 92 contacts the proximal end 106 of the movable mounting post 90 and the second end of the spring 92 contacts the terminal end of the contact finger 80 around the edge of the hole 120. With the movable mounting post 90 disposed within the channel 83 in this manner, the distal end 108 of the movable mounting post 90 extends out the hole 120 of the terminal end of the contact finger 80. As can be appreciated, the movable mounting post 90 is capable of being slidably displaced within the channel 83 along a longitudinal axis, the spring 92 naturally biasing the movable mounting post 90 from the terminal end of the contact finger 80.

Having disposed the spring 92 and the movable mounting post 90 into the channel 83 of the contact finger 80, the substrate contacting member assembly 88 is mounted onto the distal end 108 of the movable mounting post 90. The substrate contact member assembly 88 comprises a bottom susceptor contact surface 110, a lip 112, a first substrate contact surface 114 and a second substrate contact surface 116.

It should be noted that with the substrate contacting member assembly 88 mounted onto the open end in this manner, the distal end 108 of the movable mounting post 90 projects through hole 120. The substrate contacting member assembly 88, constructed preferably of a ceramic material or other materials that do not react with process chemistries, includes a circular opening which is sized and shaped to receive the distal end 108 of the movable mounting post 90. The substrate contacting member assembly 88 may be secured onto the distal end 108 of the movable mounting post 90 by using an adhesive or by sizing the post so that the distal end 108 is securely press-fit within the circular opening. In another embodiment, the movable mounting post 90 and the substrate contact member assembly 88 are integral. As can be appreciated, the substrate contact member assembly 88 prevents the spring loaded assembly 86 from completely retracting into the channel 83. Specifically, the spring 92 naturally biases the movable mounting post 90 inward away from the terminal end of the contact finger 80. However, because the substrate contacting member assembly 88 is larger than the diameter of the opening, the movable mounting post 90 is not capable of further internal displacement once the substrate contacting member assembly 88 abuts against the wall of the contact finger 80.

The contact finger 80 may be an integral part of the shadow frame 22. In another embodiment, the contact finger 80 is a separate piece that can be threadedly connected to the shadow frame 22 or attached by other means known in the art.

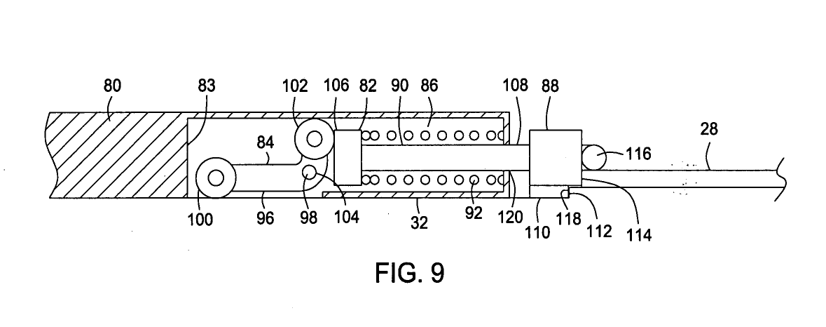

Referring to FIGS. 7-9, as the susceptor 32 and substrate 28 are raised, the substrate 28 contacts the first contact surface 100 of the hinge assembly 84. After contact between the susceptor 32 and the first contact surface 100, the hinge 96 rotates about the pivot point 104 thus causing the second contact surface 102 to physically communicate with the proximal end 106 of the movable mounting post 90 thus pushing movable mounting post 90 toward the terminal end of the contact finger 80. As movable mounting post 90 is pushed toward the terminal end of the contact finger 80, the spring 92 is compressed. As the movable mounting post 90 moves forward, the substrate contact member assembly 88 advances toward the substrate 28. When the actuator assembly 82 reaches its final position (shown in FIG. 9), the hinge assembly 84 has retracted into the contact finger 80, the spring 92 is compressed and the first contact surface member 100 is touching the susceptor 32 and the second contact surface member 102 is touching the proximal end 106 of the movable mounting post 90 of the contact finger 80. The bottom susceptor contact surface 110 is in physical communication with the susceptor 32, the lip 112 is also in contact with a ridge 118 on the susceptor 32. The ridge 118 also serves as a stopper for the spring loaded assembly 86. The first substrate contact surface 114 is in communication with the side of the substrate. This first substrate contact surface 114 helps correct the substrate 28 alignment. The second substrate contact surface 116 contacts the top surface of the substrate 28 thus helping to prevent bowing and warping of the substrate 28.

When the susceptor 32 and the substrate 28 are lowered, the hinge 96 rotates about the pivot point 104. As the hinge 96 returns to its initial position, the second contact surface 102 disengages the top of the channel 83 of the contact finger 80 and the proximal end 106 of the spring loaded assembly 86. The spring 92 decompresses thus pushing the movable mounting post 90 toward its initial position, causing the substrate contact member assembly 88 to disengage from the susceptor 32 and the substrate 28.

Referring to FIG. 3A, alignment of the shadow frame 22 is facilitated by the cooperation of an alignment recess 52 formed in the shadow frame 22 and an upper tapered surface 54 of the plurality of alignment pins 42. The alignment pins are preferably constructed of an insulator such as ceramic. As shown in FIG. 3A, the alignment pins 42 are positioned in a recessed shoulder 50 formed in the perimeter of the support member 32 and are partially disposed through the floating shadow frame 40. At an upper end, the alignment pins 42 form a tapered surface 54. The tapered surface 54 cooperates with the alignment recess 52 to urge the shadow frame 22 into a desired location relative to the support member 32, as described in greater detail below. An annular support surface 56 is provided at a mid-section of the alignment pins 42 and is adapted to support the floating shadow frame 40 with a gap between the shadow frame 40 and the support member 32.

The floating shadow frame 40 is disposed in the recessed shoulder 50 between the shadow frame 22 and the support member 32 when the shadow frame 22 is received for processing. The recessed shoulder 50 is adapted to position the floating shadow frame 40 so that an overhanging edge portion 60 of the substrate 28 extends over a portion of the floating shadow frame 40. The floating shadow frame 40 is preferably shaped substantially the same in perimeter as the shadow frame 22, i.e., rectangular for use with a rectangular substrate, and is supported by the annular support surface 56 of the alignment pins 42. Holes 58 formed in the floating shadow frame 40 allow the upper ends of the alignment pins 42 to extend therethrough. In a processing position, the floating shadow frame 40 is disposed in a gap a formed between the substrate 28 and the shadow frame 22, as shown in FIG. 2. The term “floating” is used to describe the electrical disposition of the floating shadow frame 40. Thus, as shown in FIG. 3A, the floating shadow frame 40 is disposed on an insulating member, the alignment pin 42, and maintains a spaced relationship with the support member 32.

As shown in FIG. 3A gaps 62, 64, 66 are provided between various features of the clamping and aligning assembly 30. The gaps 62, 64, 66 accommodate the thermal expansion and contraction of the clamping and aligning assembly 30 during processing. Thus, the size of the gaps 62, 64, 66 is, in part, determined by the material used to construct the floating shadow frame 40 which is preferably aluminum or ceramic. Where the floating shadow frame 40 comprises a conducting material, such as aluminum, the gaps 62 and 66 prevent contact with, and thus electrical conduction between, the support member 32 and the floating shadow frame 40. Gaps 62, 64, 66 additionally prevent rubbing contact which would create particles, or compressive loading between parts leading to cracks and chips. However, the dimensions provided herein are merely illustrative and may be changed according to a particular application.

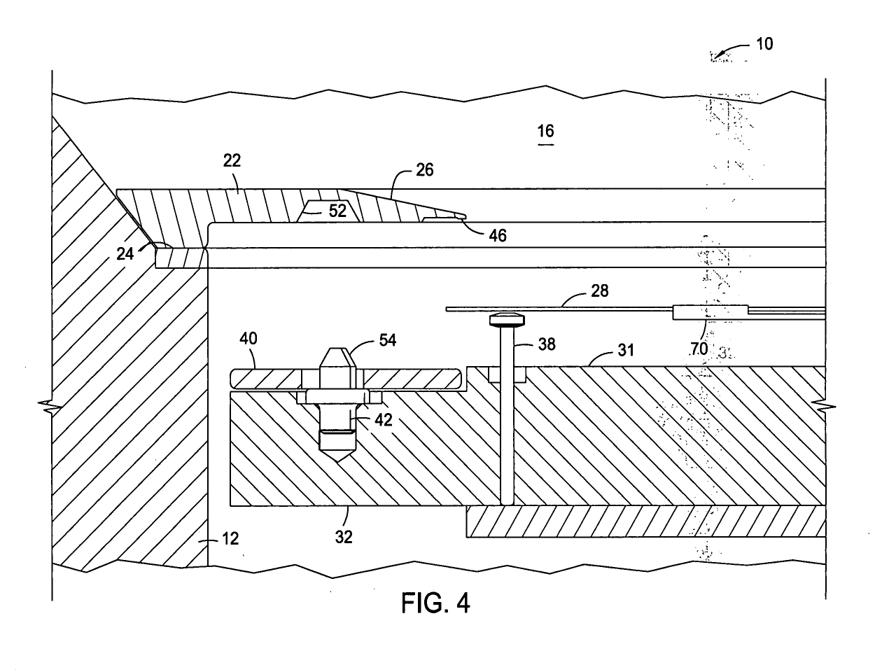

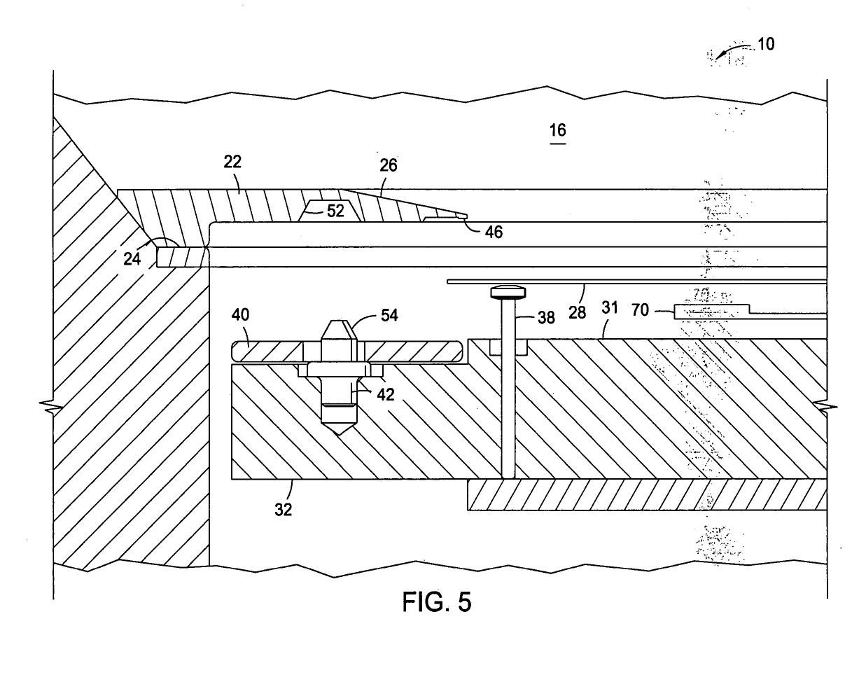

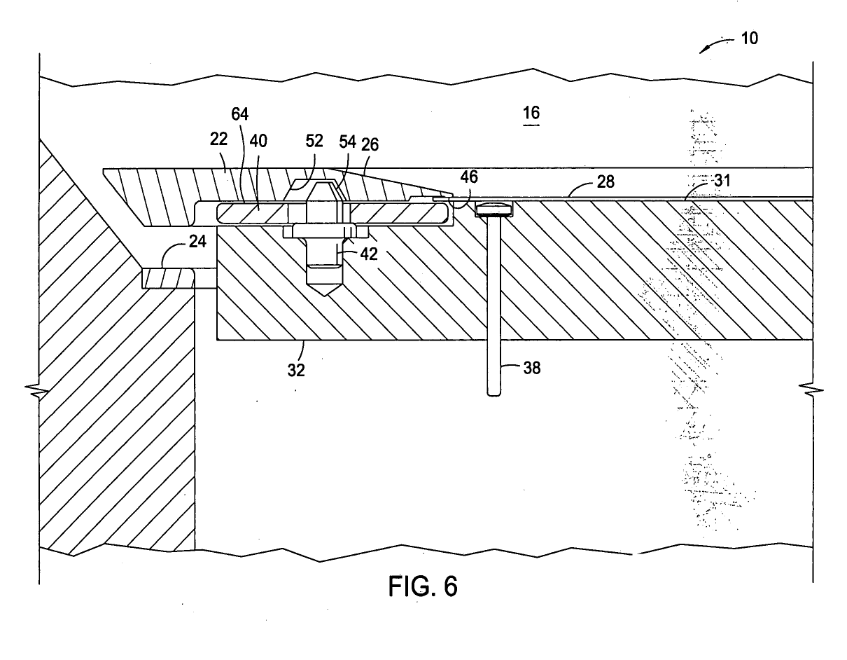

The operation of the clamping and aligning assembly 30 is more fully understood with reference to FIGS. 4-6. Initially, a substrate 28 is introduced into the processing chamber 10 through an opening 36 (shown in FIG. 1) using a conventional robot blade 70, as shown in FIG. 4. The substrate 28 is supported on an upper surface of the robot blade 70 and is positioned above the raised lift pins 38. The support member 32 and lift pins 38 are then actuated by motors 33 and 39 (shown in FIG. 1), respectively, to bring the lift pins 38 into contact with the substrate 28, thereby lifting the substrate 28 from the robot blade 70 as shown in FIGS. 4 and 5. The robot blade 70 is then retracted and the support member 32 is raised relative to the stationary lift pins 38. Upon the continuing motion of the support member 32, the upper ends of the alignment pins 42 are received by the alignment recess 52 of the shadow frame 22, as shown in FIG. 6. Any lateral offset of the shadow frame 22 relative to the support member 32 is adjusted by cooperation of the tapered surface 54 of the alignment pins 42 and the corresponding, conforming surface of the alignment recess 52. Thus, the shadow frame 22 is urged into a desired position before any contact between the shadow frame 22 and the substrate 28 occurs. Subsequently, the substrate 28 is brought into contact with the fingers 26 of the shadow frame 22, thereby lifting the shadow frame 22 from the ledge 24, as shown in FIG. 6. In a processing position, shown in FIG. 6, the shadow frame 22 is disposed on the substrate 28 positioned in the processing region 16. The fingers 26 extend over an edge of the substrate 28 and contact an upper surface thereof. Thus, only a small portion of the substrate 28 is obscured by the shadow frame 22 during processing.

In a processing position, shown in FIGS. 3A and 6, the shadow frame 22 is supported by the substrate 28 and maintains a spaced relation with the floating shadow frame 40 to define gap 64. Thus, the shadow frame 22 provides a clamping pressure on the perimeter substrate 28 during processing while maintaining an electrically insulated position relative to other chamber components. The pressure supplied by the weight of the shadow frame 22 is localized to the areas of contact, the ceramic tip, between the fingers 26 and the substrate 28. In order to prevent damage to the substrate 28, the pressure can be optimized by altering the weight of the shadow frame 22, the number of fingers, 26 and/or the contact area provided by each ceramic tip. The pressure can also be optimized by using different springs. However while additional fingers 26 may be used to reduce the pressure applied at each contact point, the number of fingers 26 is preferably minimized in order to maximize the usable space of the substrate 28. In one embodiment, shown in FIG. 2, the shadow frame comprises eight (8) fingers 26. In other embodiments, the shadow frame may comprise more or less than eight (8) fingers 26. Further, in order to reduce the potential for bowing or warping of the substrate 28, the pressure is preferably supplied directly over the outer edge of the upper surface 31 of the substrate 28 or slightly outwardly thereof, i.e., on the overhanging edge portion 60 of the substrate 28 as shown in FIG. 3. Bowing or warping typically occurs at the outer portion of a substrate resulting in a convex shape of the substrate relative to the support member 32. Thus, applying the pressure proximate the outer edge of the upper surface 31 prevents an upward bowing effect of the substrate edge.

The deposition process is initiated by introducing one or more process gases into the chamber 10 via the gas distribution plate 18 (shown in FIG. 1) and exciting the gases into a plasma state by supplying an electric field to the processing region 16, thereby forming radicals of a deposition gas which will form a thin film on the substrate. The plasma is preferably maintained over the entire upper surface of the substrate 28 to ensure uniform deposition and a maximum usable surface area on the substrate. As shown in FIG. 2, a gap a is defined between the shadow frame 22 and the substrate 28. In conventional apparatus, such a gap resulted in unwanted deposition on the support member 32 (shown in FIG. 1) and other chamber components and also provided a pathway for plasma to ground to the chamber components, thereby diminishing the plasma density at the edge of the substrate 28. The present invention overcomes the disadvantages of prior art by positioning the floating shadow frame 40 in the gap α. Further, a portion of the floating shadow frame 40 is disposed below the overhanging edge portion 60 (shown in FIG. 3) of the substrate 28. Thus, the floating shadow frame 40 and the substrate 28 cooperate to effectively seal the gap α and substantially eliminate the potential for plasma drainage to the support member 32 (shown in FIG. 1). The potential for plasma drainage is further mitigated by positioning the shadow frame 22 in a spaced relation relative to the support member 32. Such an arrangement electrically isolates the shadow frame 22 during processing when an insulative material, such as glass, is disposed between the shadow frame 22 and the support member 32. Thus, the invention reduces the grounding effect of the floating shadow frame 40 and the shadow frame 22 and prevents the charged constituents of the plasma, such as electrons, from draining out of the plasma, thereby maintaining a constant and uniform plasma. Further, the floating shadow frame 40 prevents deposition from reaching the support member 32, thereby reducing the periodic cleaning of the support member 32 which is necessary with conventional assemblies. When necessary, the floating shadow frame 40 may be removed and replaced with a clean floating shadow frame without impacting the throughput of the processing system. The removed floating shadow frame 40 can then be cleaned and recycled for later use.

While the foregoing is directed to the preferred embodiment of the present invention, other and further embodiments of the invention may be devised without departing from the basic scope thereof, and the scope thereof is determined by the claims that follow.

1. An apparatus for supporting a substrate, comprising:
a substrate support member; and
a horizontally alignable shadow frame comprising a plurality of fingers for stabilizing a substrate disposed on the substrate support member wherein the fingers comprise an actuator assembly.

2. The apparatus of claim 1, wherein the actuator assembly comprises a hinge assembly and a spring loaded assembly.

3. The apparatus of claim 2, wherein the spring loaded assembly comprises a mounting post with a spring disposed thereon wherein the mounting post is attached to a substrate contact member assembly.

4. The apparatus of claim 1 wherein the horizontally alignable shadow frame comprises a material selected from a group consisting of ceramic, aluminum, anodized aluminum, stainless steel and other alloys.

5. The apparatus of claim 1 further comprising a floating shadow frame positionable on the substrate support member wherein the floating shadow frame extends inwardly under a substrate receiving position.

6. The apparatus of claim 5, wherein the floating shadow frame comprises a material selected from a group consisting of ceramic, aluminum, and a combination thereof.

7. The apparatus of claim 1 wherein the substrate contact member assembly comprises a ceramic material.

8. The apparatus of claim 2, wherein the spring loaded assembly comprises a spring selected from a group consisting of compression springs, flat springs and coil springs.

9. A processing chamber, comprising:
an enclosure defining a process region;
a gas distribution assembly defining an upper boundary of the processing region;
a shadow frame disposed in the enclosure and positionable in the processing region, wherein the shadow frame comprises a plurality of fingers extending inwardly, wherein a terminal end of each finger comprises an actuator assembly further comprising a hinge assembly and a spring loaded assembly;
a support member movably disposed in the enclosure; and
a floating shadow frame disposed over a perimeter portion of the support member, wherein the floating shadow frame is disposed to seal a gap defined by the shadow frame and a substrate positioned on an upper surface of the support member.

10. The processing chamber of claim 9, wherein the spring loaded assembly comprises a mounting post with a spring disposed thereon wherein the mounting post is attached to a substrate contact member assembly.

11. The processing chamber of claim 9, wherein the horizontally alignable shadow frame comprises a material selected from a group consisting of ceramic, aluminum, anodized aluminum and a combination thereof.

12. The processing chamber of claim 9, wherein the floating shadow frame comprises a material selected from a group consisting of ceramic, aluminum, and a combination thereof.

13. The processing chamber of claim 10, wherein the spring is selected from a group consisting of compression springs, flat springs and coil springs.

14. The processing chamber of claim 13 wherein the spring comprises a material selected from a group consisting of aluminum, anodized aluminum, stainless steel and other alloys.

15. The processing chamber claim 9 wherein the plurality of fingers comprises a dielectric material.

16. The processing chamber of claim 9, wherein the plurality of fingers comprises a ceramic material.

17. The processing chamber of claim 9, wherein the plurality of fingers comprise a roof portion adjacent the terminal end adapted to maintain a spaced relationship with the substrate.

18. A method for processing a substrate, comprising:
supporting a substrate member;
positioning a floating shadow frame on the substrate support member wherein the floating shadow frame extends inwardly under a substrate receiving position on the support member; and
aligning a shadow frame comprising a plurality of fingers for stabilizing a substrate disposed on the substrate support member wherein the fingers comprise an actuator assembly with a substrate contact member assembly.

19. The method of claim 18, wherein the actuator assembly comprises a spring having a shape selected from a group consisting of conical, barrel, hourglass or straight.

20. The method of claim 19, wherein the spring is selected from a group consisting of compression springs, flat springs and coil springs.
